(19) United States
(12) Patent Application Publication
(10) Pub. No.: US 2005/0263766 A1
(43) Pub. Date: Dec. 1, 2005

(54) PIXEL OF A THIN FILM TRANSISTOR ARRAY SUBSTRATE AND METHOD FOR MAKING THE SAME

(76) Inventor: Hong-Da LIU, Hsin-Chu Hsien (TW)

Correspondence Address: NORTH AMERICA INTELLECTUAL PROPERTY CORPORATION, P.O. BOX 506, MERRIFIELD, VA, 22116, US

(21) Appl. No.: 10/709,766

(22) Filed: May 27, 2004

(51) Int. Cl. H01L 29/04

(52) U.S. Cl. 257/72

(57) ABSTRACT

A pixel of a thin film transistor array substrate and a method for making the same are used to reduce exposure time and prevent the pixel from being exposed to light beams with uneven light intensity in a photolithography process, where the light beams with uneven light intensity resulting from protrusions of a stage in an exposure apparatus may result in forming undesired patterns in the pixel. The pixel includes a light-shielding layer formed below a photosensitive layer to shelter portions of the pixel from the light beams in order to prevent the light beams from irradiating the protrusions of the stage. Additionally, the light-shielding layer comprising a multi-layer reflective film or a metallic material with high reflectivity functions to reflect the light beams to irradiate the photosensitive layer again, thereby reducing the exposure time required by the photolithography process.

### BACKGROUND OF INVENTION

1. Field of the Invention

The present invention relates to a pixel of a thin film transistor array substrate and a method for making the same, and more specifically, to a pixel of a thin film transistor array substrate and a method for making the same, which are capable of reducing exposure time and preventing the pixel from being exposed to exposure light beams with uneven light intensity in a photolithography process, where the exposure light beams with uneven light intensity resulting from protrusions of a stage in an exposure apparatus may result in forming undesired patterns in the pixel.

2. Description of the Prior Art

Please refer to FIG. 1. FIG. 1 is a schematic diagram illustrating a prior art pixel 100 of a thin film transistor array substrate that is undergoing a photolithography process. As shown in FIG. 1, the pixel 100 of the thin film transistor array substrate includes a substrate 111, an insulation layer 110, a passivation layer 108, an ITO (indium tin oxide) layer 106 and a photosensitive layer 104. When a photolithography process is performed, the thin film transistor array substrate is loaded into an exposure apparatus and is put on a stage 112 having a plurality of protrusions 114 for supporting the substrate 111. Then, light beams 101 are projected onto the photosensitive layer 104 through a photoresist 102. Since the photosensitive layer 104, the ITO layer 106, the passivation layer 108, the insulation layer 110 and the substrate 111 are pervious to light, the light beams 101 can pass through the pixel 100 and reach the stage 112. Additionally, because the stage 112 is composed of a material with low reflectivity and having a surface with a dark color, only a small amount of the light beams 101 can be reflected to irradiate the photosensitive layer 104 again by the stage 112. However, although the amount of light beams 118 and 120 that are reflected by the protrusions 114 and planar surfaces 116 are quite few, light intensity of the light beams 118 is quite different from that of the light beams 120 so that portions of the photosensitive layer 104 exposed to the light beams 118 do not receive the same light intensity as portions of the photosensitive layer 104 exposed to the light beams 120. Therefore, undesirable patterns 122 are formed in the photosensitive layer 104 after the photolithography process is completed as shown in FIG. 2.

As a result, it is important to develop a pixel of a thin film transistor array substrate and a method for making the same, which are capable of reducing exposure time and preventing undesirable patterns from being formed due to protrusions of a stage in an exposure apparatus when a photolithography process is performed.

### SUMMARY OF INVENTION

It is therefore a primary objective of the claimed invention to provide a pixel of a thin film transistor array substrate and a method for making the same, which are capable of preventing undesired patterns resulting from protrusions of a stage in an exposure apparatus from being formed in a photolithography process.

It is another objective of the claimed invention to provide a pixel of a thin film transistor array substrate and a method for making the same, which are capable of reducing exposure time required in a photolithography process.

According to the claimed invention, a pixel of a thin film transistor array substrate and a method for making the same are provided. The pixel includes a light-shielding layer formed below a photosensitive layer to shelter portions of the pixel from light beams generated in a photolithography process in order to prevent the light beams from irradiating protrusions of a stage, thereby eliminating undesired patterns. Additionally, the light-shielding layer comprises a metallic layer, which either a gate electrode of a thin film transistor comprises or source/drain electrodes of the thin film transistor comprise, so that the claimed invention does not need any extra process. Furthermore, the light-shielding layer comprising a multilayer reflective film or a metallic material with high reflectivity functions to reflect the light beams to irradiate the photosensitive layer again, thereby reducing the exposure time required by the photolithography process and improving a production yield.

These and other objectives of the claimed invention will no doubt become obvious to those of ordinary skill in the art after reading the following detailed description of the preferred embodiment, which is illustrated in the multiple figures and drawings.

### BRIEF DESCRIPTION OF DRAWINGS

FIG. 1 is a schematic diagram illustrating a prior art pixel of a thin film transistor array substrate that is undergoing a photolithography process.

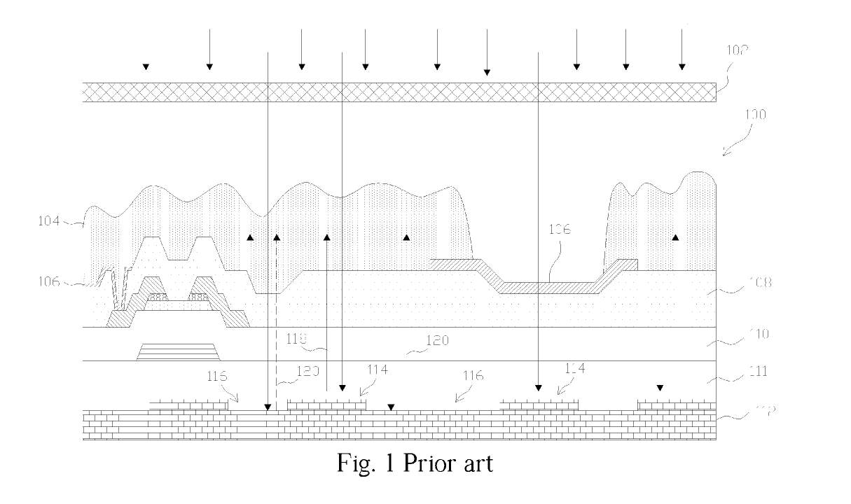

FIG. 2 illustrates undesired patterns formed in the photosensitive layer of FIG. 1.

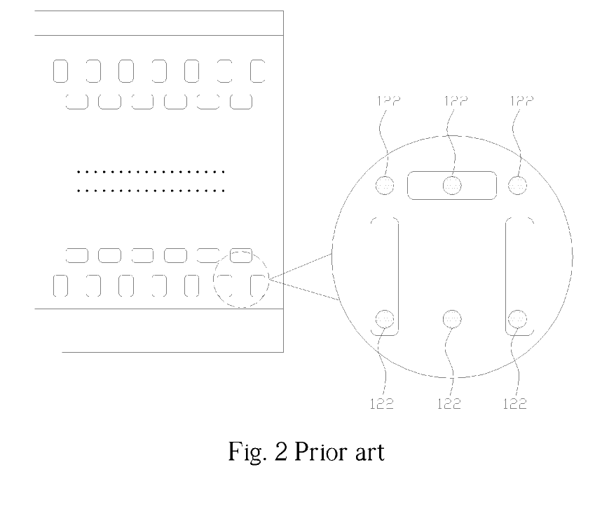

FIG. 3 is a schematic diagram illustrating a pixel of a thin film transistor array substrate that is undergoing a photolithography process according to the first embodiment of the present invention.

FIG. 4 illustrates forming a reflective layer on the photosensitive layer of FIG. 3.

FIG. 5 is a schematic diagram illustrating a pixel of a thin film transistor array substrate that is undergoing a photolithography process according to the second embodiment of the present invention.

FIG. 6 illustrates forming a reflective layer on the photosensitive layer of FIG. 5.

FIG. 7 is a schematic diagram illustrating a pixel of a thin film transistor array substrate that is undergoing a photolithography process according to the third embodiment of the present invention.

FIG. 8 is a top view of the light-shielding layer of FIG. 7.

FIG. 9 is a top view of the light-shielding layer of FIG. 7.

FIG. 10 is a top view of the reflective layer of FIG. 7.

### DETAILED DESCRIPTION

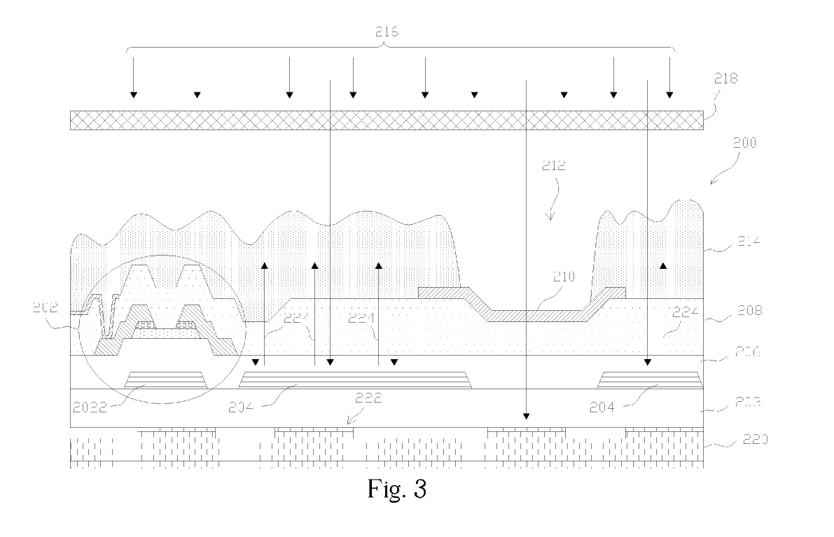

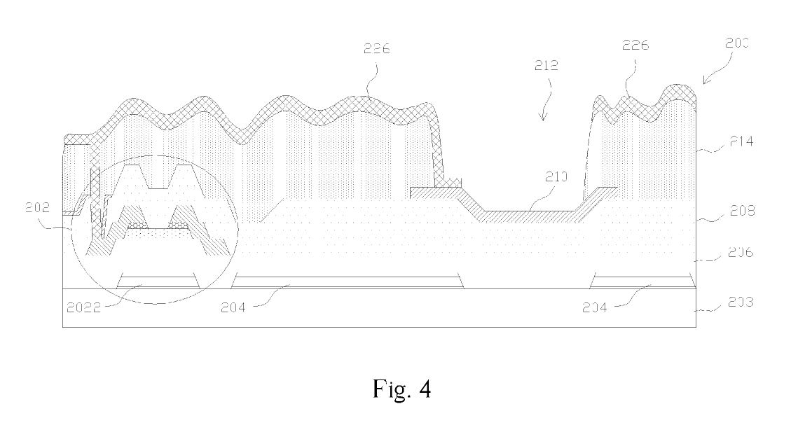

Please refer to FIG. 3. FIG. 3 is a schematic diagram illustrating a pixel 200 of a thin film transistor array substrate that is undergoing a photolithography process according to the first embodiment of the present invention. As shown in FIG. 3, the pixel 200 includes a thin film transistor 202 located on a substrate 203, a light-shielding layer 204 composed of a metallic material with high reflectivity, an insulation layer 206 positioned on the light-shielding layer 204, a passivation layer 208 covering the insulation layer 206 and the thin film transistor 202, a pervious to light layer layer 210 comprising ITO or IZO positioned on the passivation layer 208 and covering an opening 212, and a photosensitive layer 214 formed on the passivation layer 208 and surrounding the opening 212. When a photolithography process is performed, the thin film transistor array substrate is loaded into an exposure apparatus and is put on a stage 220 having a plurality of protrusions 222 for supporting the substrate 203. Then, light beams 216 are projected onto the photosensitive layer 214 through a photoresist 218. Subsequently, portions of the light beams 216 penetrate the pixel 200 through the opening 212 to reach the stage 220, while portions of the light beams 216 pass through the photosensitive layer 214, the passivation layer 208 and the insulation layer 206 to reach the light-shielding layer 204, which prevents the light beams 216 from reaching the protrusions 222 under the light-shielding layer 204 so as to avoid forming undesirable patterns. Thereafter, the photosensitive layer 214 is again exposed to light beams 224 that are reflected by the light-shielding layer 204. Since the light-shielding layer 204 is composed of a metallic material with high reflectivity, light intensity of the light beams 224 is close to that of the light beams 216, thereby largely reducing exposure time of the photolithography process and improving a production yield. After the photolithography process is completed, a reflective layer 226 is formed on the photosensitive layer 214, as shown in FIG. 4. The reflective layer 226 usually comprises aluminum, silver or an alloy comprising aluminum and silver. Additionally, the light-shielding layer 204 and a gate electrode 2022 of the thin film transistor 202 are included in the same metallic layer, and that is, the light-shielding layer 204 and the gate electrode 2022 are formed simultaneously.

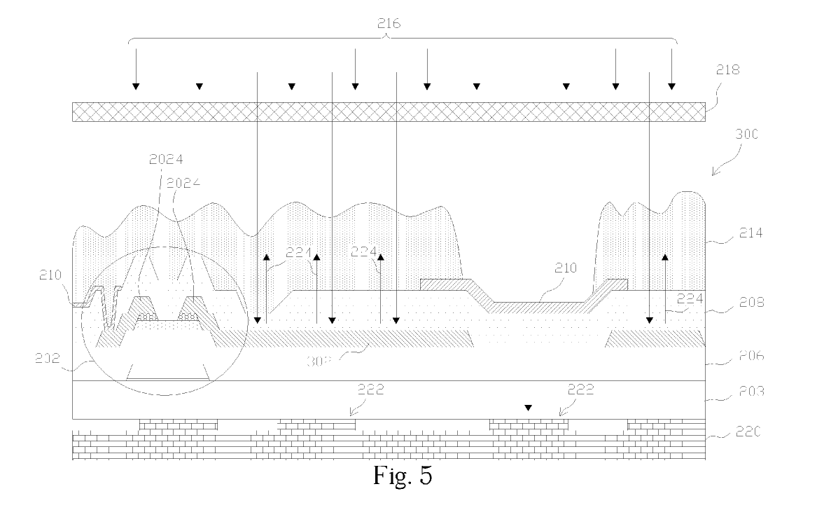

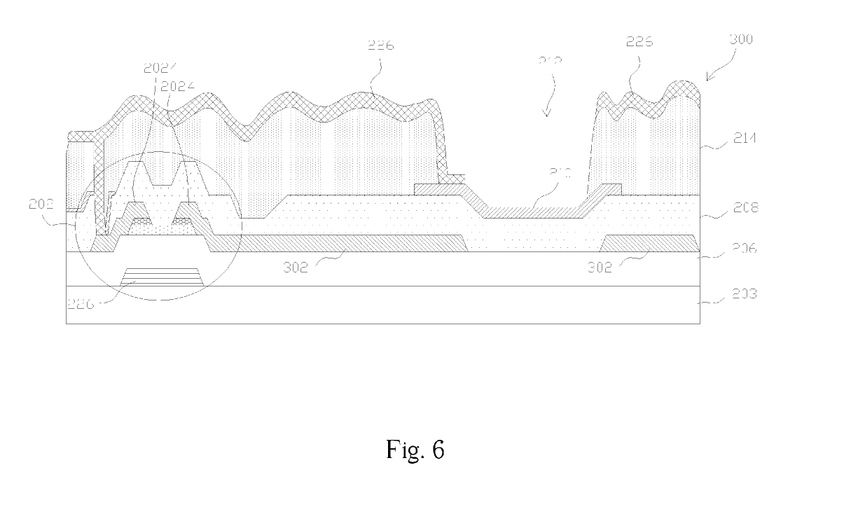

Please refer to FIG. 5. FIG. 5 is a schematic diagram illustrating a pixel 300 of a thin film transistor array substrate that is undergoing a photolithography process according to the second embodiment of the present invention. As shown in FIG. 5, the pixel 300 includes a substrate 203, a thin film transistor 202, an insulation layer 206, a passivation layer 208, a pervious to light layer 210 comprising ITO or IZO, a photosensitive layer 214, and a light-shielding layer 302 positioned between the insulation layer 206 and the passivation layer 208. Additionally, the light-shielding layer 302 and source/drain electrodes 2024 of the thin film transistor 202 are included in the same metallic layer, and that is, the light-shielding layer 302 and source/drain electrodes 2024 are formed simultaneously. As mentioned in the first embodiment of the present invention, the thin film transistor array substrate is loaded into an exposure apparatus and is put on a stage 220 having a plurality of protrusions 222 for supporting the substrate 203 when a photolithography process is performed. Then, an exposure step is performed on the photosensitive layer 214 when light beams 216 are projected onto the photosensitive layer 214 through a photoresist 218. Subsequently, portions of the light beams 216 passing through the photosensitive layer 214 and the passivation layer 208 are reflected by the light-shielding layer 302, thus preventing the light beams 216 from reaching the protrusions 222 of the stage 220. After the light beams 216 are reflected by the light-shielding layer 302, the photosensitive layer 214 is exposed to reflected light beams 224 again, which reduces exposure time of the photolithography process effectively and improves a production yield. Referring to FIG. 6, a reflective layer 226 is formed on the photosensitive layer 214 after the photolithography process is completed. The reflective layer 226 usually comprises aluminum, silver or an alloy comprising aluminum and silver.

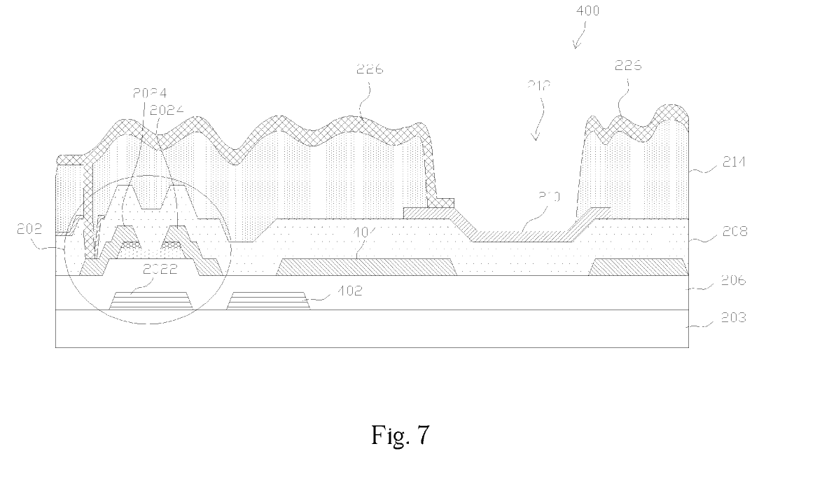

Please refer to FIG. 7. FIG. 7 is a schematic diagram illustrating a pixel 700 of a thin film transistor array substrate that is undergoing a photolithography process according to the third embodiment of the present invention. As shown in FIG. 7, the pixel 400 includes a substrate 203, a thin film transistor 202, an insulation layer 206, a passivation layer 208, a pervious to light layer 210 comprising ITO or IZO, a photosensitive layer 214, a reflective layer 226, and light-shielding layers 402 and 404. Additionally, the light-shielding layer 402 and a gate electrode 2022 of the thin film transistor 202 are included in the same metallic layer, while the light-shielding layer 404 and source/drain electrodes 2024 of the thin film transistor 202 are included in the same metallic layer. As mentioned above, the light-shielding layers 402 and 404 can prevent light beams 216 from reaching protrusions 222 of the stage 220 so that undesirable patterns can be eliminated in the photolithography process, and further, the light-shielding layers 402 and 404 also function to reflect the light beams 216 in order to reduce exposure time of the photolithography process.

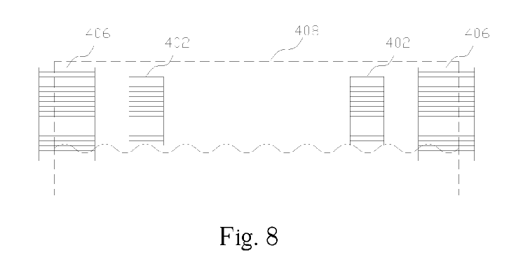

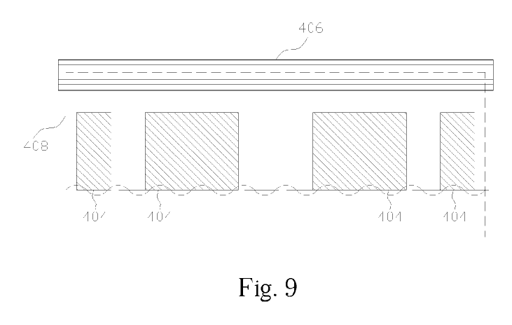

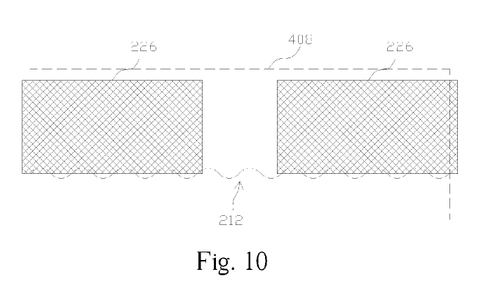

Please refer to FIG. 8 to FIG. 10. FIG. 8 is a top view of the light-shielding layer 402 shown in FIG. 7. FIG. 9 is a top view of the light-shielding layer 404 shown in FIG. 7. FIG. 10 is a top view of the reflective layer 226 shown in FIG. 7. As shown in FIG. 8 and FIG. 9, a dotted line 408 illustrates a boundary of the pixel 400, while the numeral 406 indicates bus lines. As shown in FIGS. 8-10, areas of the pixel 400, the light-shielding layer 402, the light-shielding layer 404, the reflective layer 226, and the opening 212 are respectively assumed to be A, A₁, A₂, A₃, and Aₜ. Additionally, a union of the light-shielding layer 402 and the light-shielding layer 404, i.e. (A₁∩A₂), is A₁₂. Furthermore, an intersection of the opening 212 and the union of the light-shielding layers 402 and 404 is (A₁₂∩A ₜ), and a ratio of the area of (A₁₂∩Aₜ) to the area of the pixel 400 can be represented by:
0≦((A₁₂∩Aₜ)/A)≦15% (Eq. 1)

Preferably, the value of ((A₁₂∩Aₜ)/A) is between 0 and 5%. In addition, an intersection of the reflective layer 226 and the union of the light-shielding layers 402 and 404 is (A₁₂∩A₃), and a ratio of the area of (A₁₂∩A₃) to the area of the reflective layer 226 can be represented by:
30%≦((A₁₂∩A₃)≦100% (Eq. 2)

Preferably, the value of ((A₁₂∩A₃)/A₃) is larger than 60%. According to Eq. 1 and Eq. 2, the reflective layer 226 covers most of the light-shielding layers 402 and 404, but the area Aₜ of the opening 212 is not influenced by the areas A₁ and A₂ of the light-shielding layers 402 and 404.

The above-mentioned embodiments are explained with reference to a semi-reflective thin film transistor array substrate that also can be called as a semi-transmissive thin film transistor array substrate. Additionally, the present invention can be applied in a reflective thin film transistor array substrate, and at this time, only Eq. 2 is required in the reflective thin film transistor array substrate. Furthermore, the thin film transistor array substrate can be an amorphous silicon thin film transistor array substrate or a low temperature polysilicon thin film transistor array substrate.

Usually, each of the above-mentioned gate electrode 2022, source/drain electrodes 2024, and light-shielding layers 204, 302, 402 and 404 comprises aluminum, silver, chromium, molybdenum or an alloy comprising aluminum, silver, chromium and molybdenum. Additionally, the photosensitive layer 214 comprises a positive photoresist material or a negative photoresist material. Furthermore, the light-shielding layer of the present invention also can be a multi-layer reflective film.

Moreover, the present invention can be applied in a thin film diode (TFD) display panel or a metal isolator metal (MIM) liquid crystal display panel.

In comparison with the prior art, since the present invention utilizes the light-shielding layers 204, 302, 402 and 404 to prevent light beams 216 from reaching protrusions 222 of the stage 220, undesirable patterns can be eliminated in the photolithography process. Additionally, the light-shielding layers 204, 302, 402 and 404 can be used to reflect the light beams 216 so that exposure time of the photolithography process can be reduced effectively and a production yield can be improved.

Those skilled in the art will readily observe that numerous modifications and alterations of the device may be made while retaining the teachings of the invention. Accordingly, the above disclosure should be construed as limited only by the metes and bound of the appended claims.

1. A pixel of a thin film transistor array substrate comprising:
a thin film transistor having a gate electrode comprising a first metallic layer, and source/drain electrodes comprising a second metallic layer;
a passivation layer positioned on the thin film transistor;
a photosensitive layer positioned on the passivation layer;
a reflective layer positioned on the light-sensitive layer; and
a light-shielding layer positioned below the photosensitive layer and beside the thin film transistor for preventing light beams from penetrating the light-shielding layer.

2. The pixel of claim 1 wherein the light-shielding layer comprises the first metallic layer.

3. The pixel of claim 1 wherein the light-shielding layer comprises the second metallic layer.

4. The pixel of claim 1 wherein the light-shielding layer comprises the first metallic layer and the second metallic layer.

5. The pixel of claim 1 wherein the light-shielding layer comprises a multi-layer reflective film.

6. The pixel of claim 1 wherein the thin film transistor array substrate is a semi-reflective thin film transistor array substrate.

7. The pixel of claim 1 wherein the thin film transistor array substrate is a reflective thin film transistor array substrate.

8. The pixel of claim 6 further comprising a pervious to light layer on the passivation layer, the pervious to light layer comprising ITO or IZO.

9. The pixel of claim 8 wherein the pervious to light region and the light-shielding layer have an overlapping region where the pervious to light region partially overlaps with the light-shielding layer, and a ratio of a first area of the overlapping region to a second area of the pixel is between 0 and 15%.

10. The pixel of claim 8 wherein the pervious to light region and the light-shielding layer have an overlapping region where the pervious to light region partially overlaps with the light-shielding layer, and a ratio of a first area of the overlapping region to a second area of the pixel is between 0 and 5%.

11. The pixel of claim 1 wherein the light-shielding layer and the reflective layer have an overlapping region where the light-shielding layer partially overlaps with the reflective layer, and a ratio of a first area of the overlapping region to a second area of the reflective layer is between 30% and 100%.

12. The pixel of claim 1 wherein the light-shielding layer and the reflective layer have an overlapping region where the light-shielding layer partially overlaps with the reflective layer, and a ratio of a first area of the overlapping region to a second area of the reflective layer is larger than 60%.

13. The pixel of claim 1 wherein the reflective layer comprises aluminum, silver or an alloy comprising aluminum and silver.

14. The pixel of claim 1 wherein the first metallic layer and the second metallic layer comprise aluminum, silver, chromium, molybdenum or an alloy comprising aluminum, silver, chromium and molybdenum.

15. The pixel of claim 1 wherein the photosensitive layer comprises a positive photoresist material or a negative photoresist material.

16. The pixel of claim 1 wherein the thin film transistor array substrate is an amorphous silicon thin film transistor array substrate.

17. The pixel of claim 1 wherein the thin film transistor array substrate is a low temperature polysilicon thin film transistor array substrate.

18. A method for forming a pixel of a thin film transistor array substrate comprising:
providing a substrate comprising a thin film transistor having a gate electrode comprising a first metallic layer and source/drain electrodes comprising a second metallic layer, a passivation layer formed on the thin film transistor, a photosensitive layer formed on the passivation layer, and a light-shielding layer formed below the photosensitive layer and beside the thin film transistor;
utilizing the light-shielding layer to shelter from light beams generated in a photolithography process for preventing the light beams from penetrating the light-shielding layer; and
utilizing the light-shielding layer to reflect the light beams to irradiate the photosensitive layer again for reducing exposure time of the photolithography process.

19. The method of claim 18 wherein the light-shielding layer comprises the first metallic layer.

20. The method of claim 18 wherein the light-shielding layer comprises the second metallic layer.

21. The method of claim 18 wherein the light-shielding layer comprises both the first metallic layer and the second metallic layer.

22. The method of claim 16 further comprising forming a pervious to light layer composed of ITO or IZO on the passivation layer.

23. The method of claim 22 wherein the pervious to light region and the light-shielding layer have an overlapping region where the pervious to light region partially overlaps with the light-shielding layer, and a ratio of an area of the overlapping region to an area of the pixel is between 0 and 5%.

24. The method of claim 21 wherein the pervious to light region and the light-shielding layer have an overlapping region where the pervious to light region partially overlaps with the light-shielding layer, and a ratio of an area of the overlapping region to an area of the pixel is between 0 and 5%.

25. The method of claim 18 wherein the light-shielding layer and the reflective layer have an overlapping region where the light-shielding layer partially overlaps with the reflective layer, and a ratio of an area of the overlapping region to an area of the reflective layer is between 30% and 100%.

26. The method of claim 18 wherein the light-shielding layer and the reflective layer have an overlapping region where the light-shielding layer partially overlaps with the reflective layer, and a ratio of an area of the overlapping region to an area of the reflective layer is larger than 60%.
